(19) United States
(12) Patent Application Publication
(10) Pub. No.: US 2009/0162997 A1
(43) Pub. Date: Jun. 25, 2009

(54) Thin diamond like coating for semiconductor processing equipment

(76) Inventor: Thomas E. Deacon, Cupertino, CA (US)

Correspondence Address: MURABITO HAO & BARNES LLP, Two North Market Street, Third Floor, San Jose, CA, 95113, US

(21) Appl. No.: 12/004,755

(22) Filed: Dec. 21, 2007

(51) Int. Cl. H01L 21/20; C23C 16/00

(52) U.S. Cl. 438/478; 118/720; 257/E21.131

(57) ABSTRACT

Accordingly, systems and methods of thin diamond like coatings for semiconductor processing equipment. A semiconductor substrate processing system includes an enclosure for containing a semiconductor processing gas. The enclosure has an interior surface that is at least partially coated with a diamond-like Carbon coating to a desired thickness that is less than about 0.5 μm. The enclosure may be inlet piping for conveying the semiconductor processing gas to a processing chamber for processing the semiconductor substrate, a processing chamber and/or an exhaust flume for conveying used semiconductor processing gas away from a processing chamber

### FIELD OF INVENTION

Embodiments of the present invention relate to the field of manufacturing semiconductor integrated circuits. More specifically, embodiments of the present invention relate to systems and methods of use of thin diamond like coatings for semiconductor processing equipment.

### BACKGROUND

The semiconductor industry utilizes specialized semiconductor processing systems to manufacture complex integrated circuit semiconductor devices. The highly complex, ever smaller integrated circuit devices require advanced photo-lithographic manufacturing methods, depositions and specialized doping techniques applied to a substrate or wafer, and employ corrosive and/or toxic gases in the manufacturing (fabrication) process. One such exemplary process is Silicon epitaxy, in which single crystal Silicon is grown or deposited from the gas phase, e.g., from gaseous silicon tetrachloride (SiCl₄), trichlorosilane (SiHCl₃), dichlorosilane (SiH₂Cl₂) and/or silane (SiH₄), in a high temperature, e.g., about 700° C. to 1200° C., epitaxial deposition process.

Such gases are, in general, highly corrosive, and the semiconductor industry has long sought to reduce the corrosive effect of such gases on semiconductor processing equipment. For example, the semiconductor manufacturing industry has progressed from gas piping made from “304” stainless steel to using “316” stainless steel and then using “316L” stainless steel and subsequently to using “316L” stainless steel with electropolishing in order to increase resistance to corrosion and/or to reduce the introduction of metal contaminants into the production zone.

However, with each improvement in corrosion resistance, the ever-decreasing critical dimension, “CD,” of semiconductor processing has made the integrated circuit device ever more susceptible to the effects of corrosion. For example, corrosion particles and densities that may have been acceptable for a 1.0 μm process are extremely detrimental for a 0.045 μm process. Thus, in general, the corrosion resistance of conventional art materials used for containing, flowing and processing using such corrosive gases is insufficient.

### SUMMARY OF THE INVENTION

Therefore, systems and methods of thin diamond like coatings for semiconductor processing equipment are needed. In addition, systems and methods of thin diamond like coatings for semiconductor processing equipment that reduce metal contamination evolved from gas-flow apparatus are needed. A further need exists for systems and methods of thin diamond like coatings for semiconductor processing equipment with reduced maintenance requirements are needed. A still further need exists for systems and methods of thin diamond like coatings for semiconductor processing equipment that are compatible and complimentary with existing systems and methods of semiconductor manufacturing are needed. Embodiments of the present invention provide these advantages and others as evident from the below description.

Accordingly, systems and methods of thin diamond like coatings for semiconductor processing equipment are disclosed. A semiconductor substrate processing system includes an enclosure for containing a semiconductor processing gas. The enclosure has an interior surface that is at least partially coated with a diamond-like Carbon coating to a desired thickness that is less than about 0.5 μm. The enclosure may be inlet piping for conveying the semiconductor processing gas to a processing chamber for processing the semiconductor substrate, a processing chamber and/or an exhaust flume for conveying used semiconductor processing gas away from a processing chamber

In accordance with a method embodiment of the present invention, a method of processing a semiconductor substrate includes conveying a semiconductor processing gas via inlet piping to a processing chamber. The inlet piping has an interior surface exposed to the semiconductor processing gas, and the interior surface is at least partially coated with a diamond-like Carbon coating to a desired thickness. The semiconductor substrate is processed in the processing chamber using the processing gas. The processing may include growing an epitaxial layer on the substrate, wafer cleaning, etching, chemical vapor deposition, chemical mechanical polishing, sputtering, ion implantation and/or diffusion.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings are not drawn to scale.

FIG. 1 illustrates a block diagram of a generalized semiconductor processing apparatus, in accordance with embodiments of the present invention.

FIG. 2 illustrates a side sectional view of an interior surface of a gas flow apparatus for semiconductor processing equipment, in accordance with embodiments of the present invention.

FIG. 3 illustrates a flowchart for an exemplary computer-controlled method of processing a semiconductor substrate, in accordance embodiments of the present invention.

### DETAILED DESCRIPTION

Reference will now be made in detail to various embodiments of the invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

### Notation and Nomenclature

Some portions of the detailed descriptions which follow (e.g., process 300) are presented in terms of procedures, steps, logic blocks, processing, and other symbolic representations of operations on data bits that can be performed on computer memory or controller by a computer. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system or controller by a computer system. It has proven convenient at times, principally for reasons of common usage, to refer to these signals as bits, values, elements, symbols, characters, terms, numbers, or the like.

The terms “diamond-like” and “diamond-like Carbon” are used by those of skill in the art and herein to refer to at least seven forms of amorphous Carbon materials that display some of the unique properties of natural diamond.

### Thin Diamond Like Coating for Semiconductor Processing Equipment

While exemplary embodiments of the present invention may be illustrated with respect to the formation of epitaxial layer(s) on Silicon wafers or substrates, it is appreciated that embodiments in accordance with the present invention are not limited to such exemplary devices and applications, and are well suited to many semiconductor manufacturing processes and semiconductor processing equipment types.

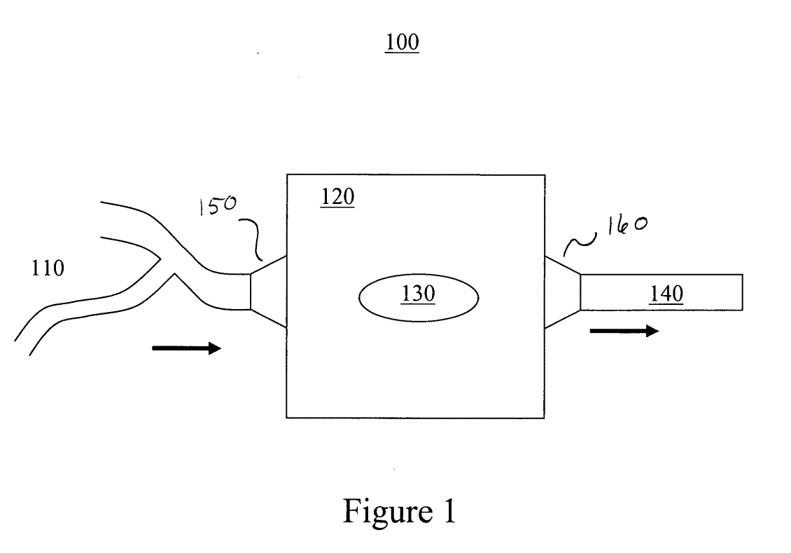

FIG. 1 illustrates a block diagram of a generalized semiconductor processing apparatus 100, in accordance with embodiments of the present invention. Processing apparatus 100 comprises inlet piping 110, processing chamber 120 and exhaust flume 140. Inlet piping 110, processing chamber 120 and exhaust flume 140 may further comprise flanges (not shown), e.g., a protruding rim or edge used to facilitate coupling with other members of processing apparatus 100. For example, inlet piping 110 may comprise an inlet piping flange for coupling to a processing chamber inlet flange of processing chamber 120. Such flanges, if present, are considered to be a part of the attached member. Thus, for example, inlet piping 110 comprises an attached flange, if present.

Processing apparatus 100 may also optionally comprise inlet manifold 150 and/or exhaust manifold 160. Inlet manifold 150 physically adapts inlet piping 110 to processing chamber 120. For example, inlet piping 110 may have a generally circular cross section, while the interior volume of processing chamber 120 is much larger and more rectangular. Inlet manifold 150 may provide a more dispersed, uniform distribution of processing gases to processing chamber 120 than would result from a more straight-forward coupling of inlet piping 110 to processing chamber 120. Inlet manifold 150 may also couple and combine multiple inlet pipes, e.g., for multiple gases. Similarly, exhaust manifold 160 may collect used processing gases from processing chamber more efficiently than a more straight-forward coupling of processing chamber 120 to exhaust flume 140.

Inlet piping 110 conveys processing gases to processing chamber 120. Inlet piping 110 may generally have a complex geometry, e.g., inlet piping 110 may be more complex than a cylindrical pipe. Such complexity may arise from having multiple sources for multiple gases, multiple inlet points, flow regulation features, inspection and maintenance ports and the like.

Processing chamber 120 is applicable to a variety of well known semiconductor processing steps, e.g., wafer cleaning, etching, chemical vapor deposition, chemical mechanical polishing, sputtering, ion implantation and/or diffusion and the like. One well known chemical vapor deposition process is the deposition or “growth” of epitaxy. Processing chamber 120 is shown with an exemplary wafer or substrate 130 inside of processing chamber 120. Among other actions, processing chamber 120 may heat its wafer carrier or susceptor to very high levels, e.g., about 700° C.-1200° C. Likewise, the wafer 130 may also be heated, e.g., to similar temperatures.

Exhaust flume 140 carries off the processing gases after their use in processing chamber 120. Exhaust flume 140 may accept process gases from one or multiple processing chambers, and may include piping that conveys used process gases to various gas capture apparatuses, e.g., recycling, recovery and/or filtering apparatuses, as well as piping that exhausts gases to the atmosphere. It is appreciated that the gases in exhaust flume 140 and/or exhaust manifold 160 may be very hot due to the high processing temperatures of processing chamber 120, and may also contain a variety of impurities resulting from the chemical reactions occurring in processing chamber 120.

As previously described, the process gases flowing in inlet piping 110, processing chamber 120 and exhaust flume 140 are, in general, highly corrosive. In addition, reaction byproducts exiting the chamber and traveling along the exhaust flume may be highly corrosive. Further, agents utilized for periodic maintenance and cleaning of such gas-flow structure, e.g., nitric acid (HNO₃) and/or hydrofluoric acid (HF), and their byproducts, may be corrosive as well. Such cleaning or cleaning byproduct chemicals are likely to form detrimental contaminants as well. Still further, periodic maintenance and cleaning generally exposes the processing equipment to “normal” atmospheric air, water, and other agents, which alone or in concert with other agents produce additional contaminants. Thus, typically, the initial processing runs after such periodic maintenance and cleaning may be highly contaminated, and generally defective, until such cleaning and other chemicals are substantially flushed from the processing system by sequential processing runs. This recovery period has a deleterious effect on production planning, resource utilization and overall processing throughput.

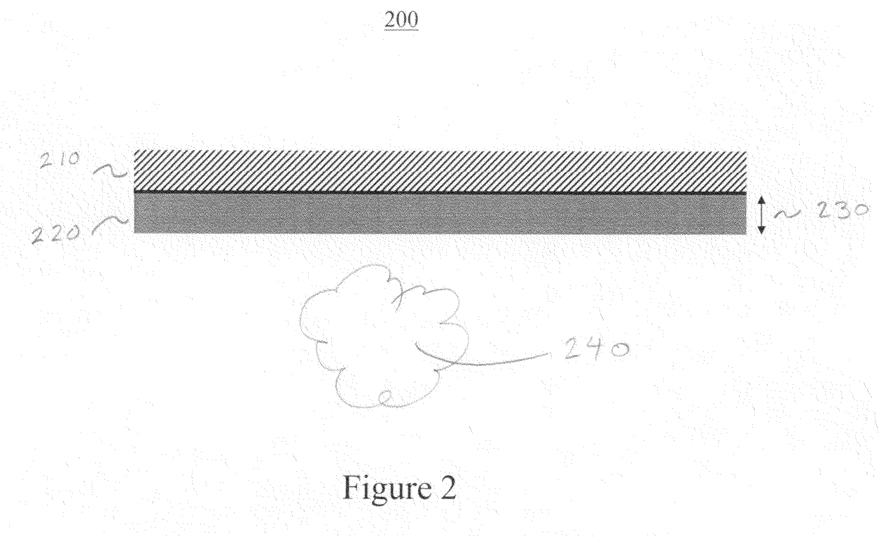

FIG. 2 illustrates a side sectional view of an interior surface 200 of a gas flow apparatus for semiconductor processing equipment, in accordance with embodiments of the present invention. Interior surface 200 may correspond to inlet piping 110, processing chamber 120, exhaust flume 140, inlet manifold 150 and/or exhaust manifold 160. In general, interior surface 200 corresponds to all interior surfaces of such a gas flow apparatus.

Interior surface 200 comprises a structural material 210, e.g., 316L stainless steel, of conventional thickness. A coating 220 of diamond-like Carbon, e.g., tetrahedral amorphous Carbon, coats an interior surface of structural material 210. Coating 220 may have a thickness 230 of 30 μm to 0.01 μm (100 Å). Coating 220 protects structural material 210 from corrosive effects of gas 240. In addition, coating 220 serves to prevent any particles or components of structural material 210 from entering gas 240, e.g., via outgassing and/or evolution.

It is to be appreciated that, in general, coating interior surfaces of semiconductor gas-flow equipment has been anathema within the semiconductor processing industry. For example, accumulated conventional industry teaching holds that “coatings come off,” and contribute to a deleterious increase in particle contamination, e.g., comprising particles from the coating, rather than reducing particle contamination, e.g., particles from the coated material.

Advantageously, coating 220 may be thinner than conventional coatings of diamond-like Carbon applied to other types of pipe. For example, complex, curving geometries common to semiconductor gas-flow components, e.g., inlet piping 110, processing chamber 120, exhaust flume 140, inlet manifold 150 and/or exhaust manifold 160 of FIG. 1, are relatively difficult to coat, as compared to straight, e.g., cylindrical, pipes, or pipes with a large radius of curvature. A relatively thin coating, e.g., less than 0.5 μm, beneficially reduces stresses in the coating material, advantageously increasing adherence of the coating to the substrate, e.g., structural material 210, and decreasing cracks and flaking in and of the coating, thereby reducing contamination directly from the coating material.

In addition, a “thinner” coating 220 is generally beneficial, in comparison to a “thicker” coating, in terms of manufacturing cost, including coating process time, energy required and amount of materials consumed. Thus, there are numerous benefits to making coating 220 thinner than under the conventional art.

It is to be appreciated that a beneficial reduction in contaminants from gas-flow equipment, e.g., two to three times fewer metal impurities evolved from metal structures of processing equipment, does not necessarily require full and complete coating coverage of all wetted, or contacted or exposed surfaces. For example, coating one half of the interior surface area of a pipe may result in a reduction to one half of the previous level of metal contamination.

Another exemplary partial coating approach may be to coat those exposed surfaces that produce, or are considered most likely to produce, the most contamination. For example, areas where the gas(es) are hottest, e.g., processing chamber 120, or portions of inlet piping 110, inlet manifold 150, exhaust manifold 160 or exhaust flume 140 near processing chamber 120, may be likely sources of contamination products. Coating such portions of gas-flow apparatus may achieve greater reduction in contamination relative to coating other portions of gas-flow apparatus.

Further, some portions of a gas-flow apparatus may convey primarily non-corrosive gases. For example, Hydrogen (H₂) is commonly used as a mainstream or carrier gas in chemical vapor deposition processes. Hydrogen is generally non-corrosive to stainless steel. Thus, relatively little reduction in metal contamination may be achieved by coating portions of a gas-flow apparatus that primarily convey only non-corrosive gases, e.g., Hydrogen piping prior to mixing with other corrosive gases, e.g., dichlorosilane (SiH₂Cl₂).

It is appreciated that there is typically some backflow, or flow of gases in opposition to the overall flow, present in such a gas flow manufacturing process. For example, some gases may backflow, e.g., flow against the predominate flow, from exhaust flume 140 or exhaust manifold 160 back into processing chamber 120 (FIG. 1). Thus, it is possible for corrosion products evolved from exhaust manifold 160 or exhaust flume 140 to enter processing chamber 120, to the detriment of the manufacturing process, even though exhaust manifold 160 and exhaust flume 140 are nominally “down stream” from the processing chamber 120. Similarly, corrosive gases may backflow into piping primarily intended to convey non-corrosive gases. Consequently, a beneficial reduction in corrosion may be obtained by coating portions of gas-flow apparatus based upon backflow characteristics.

It is of course understood that contamination is a highly non-linear process, and coatings of wetted areas may not necessarily produce linear reductions in contaminants in proportion to the wetted area coated. Nevertheless, though analysis and experimentation, a beneficial reduction in contaminants may be achieved through a less than complete coating, e.g., coating 200, of all exposed surfaces in gas flow equipment, e.g., inlet piping 110, processing chamber 120, exhaust flume 140, inlet manifold 150 and/or exhaust manifold 160 of FIG. 1.

Thus, in accordance with embodiments of the present invention, coating 200 need not be complete, e.g., covering all wetted surfaces, or contiguous. As a beneficial result, a manufacturer of semiconductor process equipment may determine that it is not necessary to coat certain portions of gas-flow equipment. For example, it may be relatively difficult to apply a coating to complex geometrical surfaces of certain equipment. Rather, a beneficial reduction in contamination in the processing zone may be achieved by coating other, less complex, surfaces.

Alternatively, a manufacturer of semiconductor process equipment may attempt to apply a very thin coating to such complex geometrical surfaces. As described previously, such thin coatings are more likely to adhere since they are under less stress than relatively thicker coatings. Beneficially, any gaps in coating coverage that may result from attempts to produce a relatively thin coating are not catastrophic, and may produce a desirable decrease in contamination within the overall system.

As previously discussed, gas-flow apparatus, e.g., as illustrated in FIG. 2, generally requires periodic maintenance and cleaning. In accordance with embodiments of the present invention, a thin diamond-like Carbon coating, e.g., coating 220, applied to at least portions of interior wetted surfaces of such gas-flow apparatus, may reduce the amount and/or frequency of periodic maintenance and cleaning activities, e.g., from once per quarter to once per year. For example, a coated piping segment may be “easier” to clean than a conventional piping segment. In addition, such coatings may reduce the post-maintenance time and/or number of process runs required to “flush” the system and obtain desirable process yields. For example, fewer cleaning actions using less aggressive cleaning agents may be required to clean a coated piping segment in comparison to a conventional piping segment. Further, such less aggressive cleaning agents may present less hazards to personnel, resulting in advantageous heath and safety benefits to employer and employees. Such numerous additive benefits of reduced maintenance may yield great financial benefits to a semiconductor manufacturer, e.g., increased overall throughput due to less “down time,” in addition to improved yield, e.g., due to less contamination, during “normal” processing.

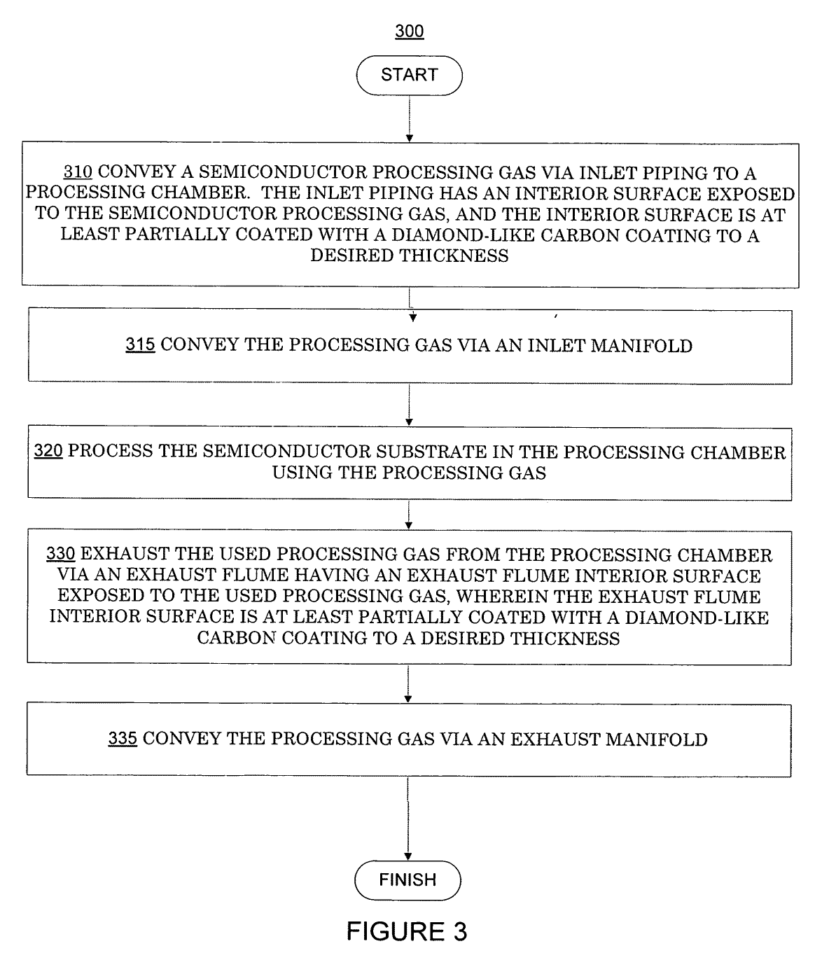

FIG. 3 illustrates a flowchart for an exemplary computer-controlled method 300 of processing a semiconductor substrate, in accordance embodiments of the present invention. In 310, a semiconductor processing gas is conveyed via inlet piping to a processing chamber. Exemplary processing gases include without limitation silicon tetrachloride (SiCl₄), trichlorosilane (SiHCl₃), dichlorosilane (SiH₂Cl₂), silane (SiH₄) and/or hydrochloric acid (HCl). The inlet piping has an interior surface exposed to the semiconductor processing gas. The interior surface is at least partially coated with a diamond-like Carbon coating to a desired thickness.

In one embodiment, the desired thickness may be less than about 0.5 μm. It is appreciated that embodiments in accordance with the present invention are well suited to other thickness of diamond-like Carbon coating as well. In another embodiment, the diamond-like Carbon coating substantially comprises tetrahedral amorphous Carbon. It is further appreciated that embodiments in accordance with the present invention are well suited to coatings comprising other forms of diamond-like Carbon.

In 320, the semiconductor substrate is processed in the processing chamber using the processing gas. In accordance with embodiments of the present invention, the processing may comprise growing an epitaxial layer on the substrate, wafer cleaning, etching, chemical vapor deposition, chemical mechanical polishing, sputtering, ion implantation and/or diffusion. In accordance with embodiments of the present invention, the processing chamber may be at least partially coated with a diamond-like Carbon coating to a desired thickness that is less than about 0.5 μm.

In optional 315, the processing gas is conveyed from the inlet piping, e.g., inlet piping 110 (FIG. 1), to the processing chamber, e.g., processing chamber 120 (FIG. 1), via an inlet manifold, e.g., inlet manifold 150 (FIG. 1).

In optional 330, the used processing gas is exhausted from the processing chamber via an exhaust flume having an exhaust flume interior surface exposed to the used processing gas. The exhaust flume interior surface is at least partially coated with a diamond-like Carbon coating to a desired thickness.

In optional 335, the processing gas is conveyed from the processing chamber, e.g., processing chamber 120 (FIG. 1), to the, exhaust flume, e.g., exhaust flume 140 (FIG. 1), via an exhaust manifold, e.g., exhaust manifold 160 (FIG. 1).

Embodiments in accordance with the present invention provide systems and methods of thin diamond like coatings for semiconductor processing equipment. Embodiments in accordance with the present invention also provide for systems and methods of thin diamond like coatings for semiconductor processing equipment that reduce metal contamination evolved from gas-flow apparatus. In addition, systems and methods of thin diamond like coatings for semiconductor processing equipment with reduced maintenance requirements are provided. Further, embodiments in accordance with the present invention provide for systems and methods of thin diamond like coatings for semiconductor processing equipment that are compatible and complimentary with existing systems and methods of semiconductor manufacturing.

Various embodiments of the invention are thus described. While the present invention has been described in particular embodiments, it should be appreciated that the invention should not be construed as limited by such embodiments, but rather construed according to the below claims.

What is claimed is:

1. A semiconductor substrate processing system comprising:
an enclosure for containing a semiconductor processing gas, said enclosure having an interior surface; and
wherein said interior surface is at least partially coated with a diamond-like Carbon coating to a desired thickness that is less than about 0.5 μm.

2. The semiconductor substrate processing system of claim 1 wherein said enclosure comprises a processing chamber for processing said semiconductor substrate.

3. The semiconductor substrate processing system of claim 1 wherein said enclosure comprises inlet piping for conveying said semiconductor processing gas to a processing chamber for processing said semiconductor substrate.

4. The semiconductor substrate processing system of claim 1 wherein said enclosure comprises an inlet manifold for coupling said inlet piping to said processing chamber.

5. The semiconductor substrate processing system of claim 3 wherein said diamond-like Carbon coating is applied to portions of said inlet piping that nominally convey non-corrosive gas.

6. The semiconductor substrate processing system of claim 1 wherein said enclosure comprises an exhaust flume for conveying used semiconductor processing gas away from a processing chamber for processing said semiconductor substrate.

7. The semiconductor substrate processing system of claim 6 wherein said enclosure comprises an exhaust manifold for coupling said processing chamber to said exhaust flume.

8. The semiconductor substrate processing system of claim 7 wherein said diamond-like Carbon coating is applied to portions of said exhaust manifold that may convey said semiconductor processing gas back to said processing chamber.

9. The semiconductor substrate processing system of claim 6 wherein said diamond-like Carbon coating is applied to portions of said exhaust flume that may convey said semiconductor processing gas back to said processing chamber.

10. The semiconductor substrate processing system of claim 1 wherein said diamond-like Carbon coating on said interior surface is sufficient to reduce metal contamination to said semiconductor substrate by at least 50% relative to an uncoated enclosure.

11. The semiconductor substrate processing system of claim 1 wherein said diamond-like Carbon coating substantially comprises tetrahedral amorphous Carbon.

12. A method of processing a semiconductor substrate, said method comprising:
conveying a semiconductor processing gas via inlet piping to a processing chamber,
wherein said inlet piping has an interior surface exposed to said semiconductor processing gas,
wherein said interior surface is at least partially coated with a diamond-like Carbon coating to a desired thickness; and
processing said semiconductor substrate in said processing chamber using said processing gas.

13. The method of claim 12 wherein said processing comprises growing an epitaxial layer on said semiconductor substrate.

14. The method of claim 12 wherein said processing comprises at least one of wafer cleaning, etching, chemical vapor deposition, chemical mechanical polishing, sputtering, ion implantation and diffusion.

15. The method of claim 12 wherein said diamond-like Carbon coating substantially comprises tetrahedral amorphous Carbon.

16. The method of claim 12 wherein said desired thickness of said diamond-like Carbon coating is less than about 0.5 μm.

17. The method of claim 12 further comprising exhausting used processing gas from said processing chamber via an exhaust flume having an exhaust flume interior surface exposed to said used processing gas, wherein said exhaust flume interior surface is at least partially coated with a diamond-like Carbon coating to a desired thickness.

18. The method of claim 12 wherein an interior surface of said processing chamber is at least partially coated with a diamond-like Carbon coating to a desired thickness that is less than about 0.5 μm.

19. A semiconductor substrate processing system comprising:
a processing chamber for processing a semiconductor substrate, said processing employing a semiconductor processing gas;
inlet piping for conveying said semiconductor processing gas to said processing chamber;
an exhaust flume for conveying used semiconductor processing gas away from said processing chamber; and
wherein interior surfaces of said processing chamber, said inlet piping and said exhaust flume are at least partially coated with a diamond-like Carbon coating to a desired thickness.

20. The semiconductor substrate processing system of claim 19 wherein said diamond-like Carbon coating substantially comprises tetrahedral amorphous Carbon.

21. The semiconductor substrate processing system of claim 19 wherein said diamond-like Carbon coating is less than about 0.5 μm thick.

22. The semiconductor substrate processing system of claim 19 wherein metal contaminants in said processing chamber evolved from interior surfaces of said processing chamber, said inlet piping and/or said exhaust flume are reduced by at least 50% relative to uncoated said processing chamber, said inlet piping and/or said exhaust flume.

23. The semiconductor substrate processing system of claim 19 wherein regular maintenance of said processing chamber, said inlet piping and/or said exhaust flume is reduced by at least 50% relative to uncoated said processing chamber, said inlet piping and/or said exhaust flume.
